(19) United States
(12) Patent Application Publication
(10) Pub. No.: US 2024/0213268 A1
(43) Pub. Date: Jun. 27, 2024

(54) CHIP ON FILM PACKAGE AND DISPLAY APPARATUS INCLUDING THE SAME

(71) Applicant: SAMSUNG ELECTRONICS CO., LTD., SUWON-SI (KR)

(72) Inventor: Na Rae SHIN, Suwon-si (KR)

(21) Appl. No.: 18/490,063

(22) Filed: Oct. 19, 2023

(30) Foreign Application Priority Data
Dec. 22, 2022 (KR) 10-2022-0181412

(51) Int. Cl. H01L 27/12; H01L 25/075; H01L 25/16; H01L 33/48; H01L 33/62

(52) U.S. Cl. CPC H01L 27/124; H01L 25/0753; H01L 25/167; H01L 33/486; H01L 33/62

(57) ABSTRACT

There is provided a chip on film package. The chip on film package includes a film substrate including an upper layer extending in first and second directions opposite to each other and a lower layer facing the upper layer, and having a cutting line formed thereon, first and second semiconductor chips disposed on the upper layer within an area of the cutting line, first and second connection wirings connected to the first and second semiconductor chips and extending toward the first and second directions, respectively, and a test pad connected to at least one of the first and second connection wirings and disposed on the lower layer, within the area of the cutting line.

### CROSS-REFERENCE TO RELATED APPLICATION

This application claims priority from Korean Patent Application No. 10-2022-0181412 filed on Dec. 22, 2022, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a chip on film package and a display apparatus including the same, and more particularly, to a chip on film package in which heterogeneous semiconductor chips are disposed, and a display apparatus including the same.

### 2. Description of the Related Art

A chip on film (COF) package includes a semiconductor chip mounted on a base film, and the mounted semiconductor chip may be electrically connected to an external apparatus through connection wirings and pads connected to the connection wirings on the base film.

Recently, as the miniaturization of a bezel and the thinning of a panel are further required in a display apparatus, types and the number of semiconductor chips mounted in one chip on film package tend to gradually increase.

### SUMMARY

Aspects of the present disclosure provide a light and thin component by changing positions of test pads in one chip on film package in which heterogeneous semiconductor chips are disposed.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some exemplary embodiments of the present disclosure, a chip on film package includes a film substrate including an upper layer extending in first and second directions opposite to each other and a lower layer facing the upper layer, and having a cutting line formed thereon, first and second semiconductor chips disposed on the upper layer within an area of the cutting line, first and second connection wirings connected to the first and second semiconductor chips and extending toward the first and second directions, respectively, and a test pad connected to at least one of the first and second connection wirings and disposed on the lower layer, within the area of the cutting line.

According to some exemplary embodiments of the present disclosure, a chip on film package includes a film substrate including an upper layer and a lower layer facing each other and having a cutting line formed thereon, first and second connection wirings electrically connected to a display panel and a driving printed circuit board, respectively, first to third semiconductor chips electrically connected to the first and second connection wirings, on the upper layer of the film substrate, a test pad disposed inside the cutting line and electrically connected to at least one of the first and second connection wirings, and a test pad connection via penetrating through the film substrate, wherein the test pad is disposed on the lower layer of the film substrate.

According to some exemplary embodiments of the present disclosure, a display apparatus includes a chip on film package including a film substrate including an upper layer extending in first and second directions opposite to each other and a third direction crossing each of the first and second directions and a lower layer facing the upper layer and having a cutting line formed thereon, a display panel formed on a first side of the chip on film package, and a driving printed circuit board formed on a second side of the chip on film package, wherein the chip on film package includes first to third semiconductor chips disposed on the upper layer within an area of the cutting line, first to third connection wirings connected to the first to third semiconductor chips, respectively, and electrically connected to the display panel and the driving printed circuit board, connection vias penetrating through the film substrate and connected to the first to third connection wirings, and a test pad connected to at least one of the first to third connection wirings through the connection vias and disposed on the lower layer, within the area of the cutting line.

Detailed contents of other exemplary embodiments are described in a detailed description and are illustrated in the drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an illustrative layout diagram for describing a display apparatus including a chip on film package according to some exemplary embodiments of the present disclosure;

FIGS. 2 and 3 are schematic views for describing a chip on film package according to some exemplary embodiments of the present disclosure;

FIG. 4 is an enlarged view of area R1 of FIG. 2;

FIG. 5 is an enlarged view of area R1′ of FIG. 3;

FIG. 6 is a cross-sectional view taken along line A-A′ of FIGS. 4 and 5;

FIG. 7 is a schematic view for describing a chip on film package according to some exemplary embodiments of the present disclosure, and is a view corresponding to FIG. 6;

FIG. 8 is a schematic view for describing a chip on film package according to some exemplary embodiments of the present disclosure;

FIG. 9 is an enlarged view of area R2′ of FIG. 8;

FIG. 10 is a cross-sectional view taken along line B-B′ of FIG. 9;

FIGS. 11 and 12 are schematic views for describing a chip on film package according to some exemplary embodiments of the present disclosure;

FIG. 13 is a schematic view for describing a chip on film package according to some exemplary embodiments of the present disclosure;

FIGS. 14 and 15 are schematic views for describing a chip on film package according to some exemplary embodiments of the present disclosure; and

FIG. 16 is a schematic view for describing a chip on film package according to some exemplary embodiments of the present disclosure.

### DETAILED DESCRIPTION OF THE EMBODIMENTS

Hereinafter, exemplary embodiments of the present disclosure will be described in detail with reference to the accompanying drawings. The same components in the drawings will be denoted by the same reference numerals, and an overlapping description thereof will be omitted.

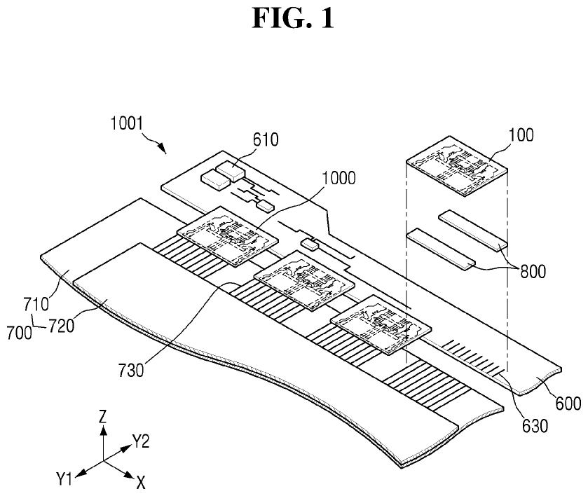

FIG. 1 is an illustrative layout diagram for describing a display apparatus including a chip on film package according to some exemplary embodiments of the present disclosure.

Referring to FIG. 1, a display apparatus 1001 may include at least one chip on film package 1000, a driving printed circuit board 600, and a display panel 700.

For example, the display panel 700 may be formed on a first side of the chip on film package 1000, and the driving printed circuit board 600 may be formed on a second side of the chip on film package 1000 opposite to the first side. The display panel 700 can be spaced apart from the driving printed circuit board 600, where the display panel 700 and the driving printed circuit board 600 can be separated by a gap. The chip on film package 1000 can be athwart a gap between the display panel 700 and the driving printed circuit board 600.

The chip on film package 1000 may be a package including a semiconductor chip, which is a display driver IC (DDI). Heterogeneous semiconductor chips may be disposed in one chip on film package 1000. For example, the semiconductor chips may include a source driving chip and a gate driving chip. A plurality of chip on film packages 1000 can be on the display panel 700 and the driving printed circuit board 600.

The chip on film package 1000 may be positioned between the driving printed circuit board 600 and the display panel 700 and be connected to each of the driving printed circuit board 600 and the display panel 700. The chip on film package 1000 may receive a signal output from the driving printed circuit board 600 and transmit the signal to the display panel 700.

One or more driving circuit chips 610 capable of simultaneously or sequentially applying power and signals to the chip on film package 1000 may be mounted on the driving printed circuit board 600. The one or more driving circuit chips 610 can be electrically connected to the one or more chip on film packages 1000 through driving connection wirings 630. Each of the one or more chip on film packages 1000 can be electrically connected to the display panel 700 through panel connection wirings 730.

The display panel 700 may be, for example, a liquid crystal display (LCD) panel, a light emitting diode (LED) panel, an organic LED (OLED) panel, a plasma display panel (PDP), or the like.

The chip on film package 1000 may be electrically connected to each of driving connection wirings 630 of the driving printed circuit board 600 and panel connection wirings 730 of the display panel 700, where the chip on film packages 1000 can electrically interconnect the panel connection wirings 730 and driving connection wirings 630.

In some exemplary embodiments, one chip on film package 1000 may be connected between the driving printed circuit board 600 and the display panel 700. For example, when the display panel 700 is for providing a screen of a small area like a mobile phone or supports a relatively low resolution, the display apparatus 1001 may include one chip on film package 1000.

In some other exemplary embodiments, a plurality of chip on film packages 1000 may be connected between the driving printed circuit board 600 and the display panel 700. For example, when the display panel 700 is for providing a screen of a great area like a television or supports a relatively high resolution, the display apparatus 1001 may include a plurality of chip on film packages 1000.

The chip on film package 1000 may be connected to only one side of the display panel 700. However, the present disclosure is not limited thereto, and one or a plurality of chip on film packages 1000 may also be connected to each of two or more sides of the display panel 700.

The display panel 700 may include a transparent substrate 710, an image area 720 formed on the transparent substrate 710, and the panel connection wirings 730. The transparent substrate 710 may be, for example, a glass substrate or a transparent flexible substrate. A plurality of pixels of the image area 720 may be connected to a plurality of panel connection wirings 730 corresponding thereto and operated according to a signal provided by the semiconductor chip mounted in the chip on film package 1000.

The chip on film package 1000 may have input pads formed at one end thereof and have output pads formed at the other end thereof, where the input pads can be located at a first end and the output pads can be located at a second end opposite the first end. The input pads may be connected to the driving connection wiring 630 of the driving printed circuit board 600, and the output pads may be connected to the panel connection wiring 730 of the display panel 700 by anisotropic conductive layers 800 with a one-to-one relationship, where, for example, a first input pad can be connected to a first driving connection wire, and a first output pad can be connected to a first panel connection wire.

The anisotropic conductive layer 800 may be, for example, an anisotropic conductive film or an anisotropic conductive paste. The anisotropic conductive layer 800 may have a structure in which conductive particles are dispersed in an insulating adhesive layer.

For example, the anisotropic conductive layers 800 may have anisotropic electrical characteristics that conduction occurs only in an electrode direction (vertical direction) at the time of connection and insulation occurs in a direction between neighboring electrodes (horizontal direction). When adhesives are melted by applying heat and pressure to such anisotropic conductive layers 800, the conductive particles may be arranged and conducted between opposing electrodes, for example, between the input pads and the drive connection wirings 630 and between the output pads and the panel connection wirings 730, while the neighboring electrodes may be filled with the adhesives to be insulated from each other.

Hereinafter, a chip on film package 1000 according to the technical idea of the present disclosure will be described in detail.

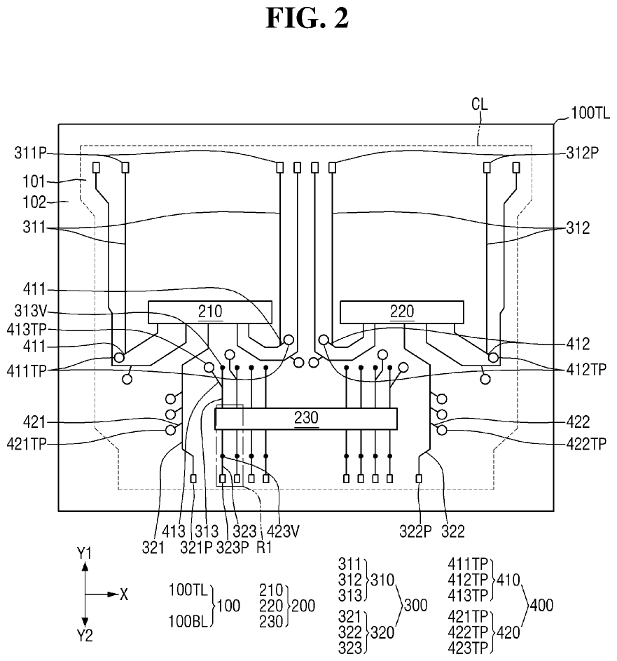

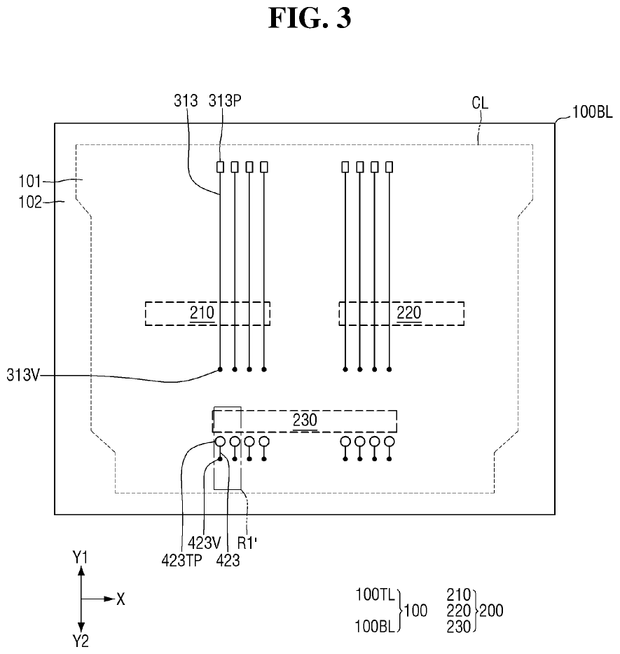

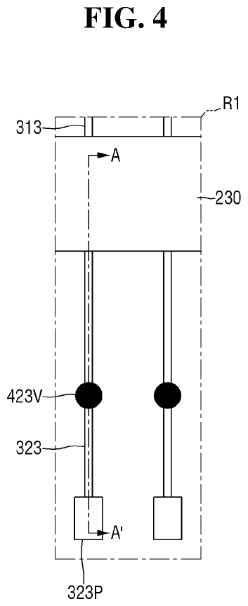

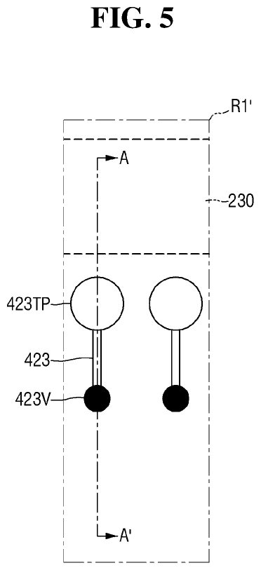

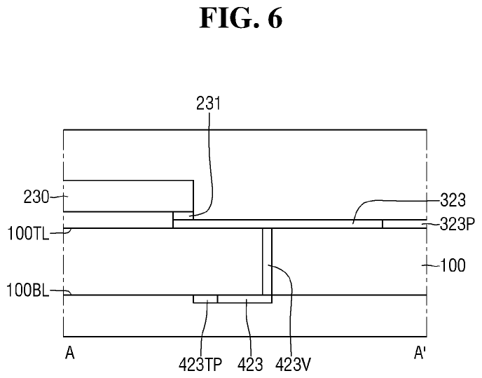

FIGS. 2 and 3 are schematic views for describing a chip on film package according to some exemplary embodiments of the present disclosure. FIG. 4 is an enlarged view of area R1 of FIG. 2. FIG. 5 is an enlarged view of area R1′ of FIG. 3. FIG. 6 is a cross-sectional view taken along line A-A′ of FIGS. 4 and 5.

Referring to FIGS. 2 and 3, a chip on film package 1000 according to some exemplary embodiments may include a film substrate 100, semiconductor chips, 210, 220, 230, connection wirings 300, and test pads 400.

The film substrate 100 may include an upper layer 100TL and a lower layer 100BL facing each other. The film substrate 100 may extend in first-first and first-second directions Y1 and Y2 opposite to each other and in a second direction X crossing each of the first-first and first-second directions Y1 and Y2. This may also be described as a film substrate 100 including an upper layer 100TL extending in a first direction and a second direction opposite to each other, and the upper layer 100TL further extends in a third direction crossing each of the first and second directions.

The film substrate 100 may be a flexible film including polyimide, which is a material having an excellent coefficient of thermal expansion and durability. However, a material of the film substrate 100 is not limited thereto, and for example, the film substrate 100 may be made of a synthetic resin such as an epoxy-based resin, acrylic, polyether nitrile, polyether sulfone, polyethylene terephthalate or polyethylene naphthalate.

The film substrate 100 may include a circuit area 101 disposed inside a cutting line CL and a peripheral area 102 disposed around the circuit area. The circuit area 101 may be an area in which the semiconductor chips 210, 220, 230 are mounted. In some exemplary embodiments, the cutting line CL may be a virtual dividing line. A film substrate 100 can include an upper layer 100TL extending in a first direction and a second directions opposite to each other and a lower layer 100BT facing the upper layer, and having a cutting line formed thereon, with the thickness of the film substrate 100 between the upper layer 100TL and the lower layer 100BT.

In various embodiments, protective layers for protecting the connection wirings 300 from external physical and/or chemical damage may be formed on the upper layer 100TL and the lower layer 100BL of the film substrate 100. The protective layers may cover the connection wirings 300 so as to expose at least portions of the connection wirings 300 formed on the upper layer 100TL and the lower layer 100BL of the film substrate 100.

The protective layer may be formed of, for example, solder resist or dry film resist. However, the present disclosure is limited thereto, and the protective layer may also be formed of a general insulating film based on silicon oxide or silicon nitride.

The semiconductor chips may include a plurality of first to third semiconductor chips 210, 220, and 230. For example, the first and second semiconductor chips 210 and 220 may be spaced apart from each other in the second direction X, and the third semiconductor chip 230 may be spaced apart from the first and second semiconductor chips 210 and 220 in the first-first and first-second directions Y1 and Y2. However, a positional relationship between the semiconductor chips 210, 220, and 2300 is not limited to that illustrated in the drawings. While three semiconductor chips are illustrated in the drawings, additional or fewer semiconductor chip may be located on the film substrate 100.

The semiconductor chip may be a DDI used to drive a display. For example, the semiconductor chip may be a source driving chip generating an image signal using a data signal transmitted from a timing controller and outputting the image signal to the display panel 700 (see FIG. 1). Alternatively, the semiconductor chip may be a gate driving chip outputting scan signals including turn-on/off signals of transistors to the display panel 700 (see FIG. 1).

For example, the third semiconductor chip 230 may be a gate driving chip, and the first and second semiconductor chips 210 and 220 may be source driving chips. It has been illustrated in the drawings that the number of semiconductor chips 200 is three, but the number of semiconductor chips is not limited thereto.

In addition, the semiconductor chip is not limited to the gate driving chip or the source driving chip. For example, when the chip on film package 1000 is coupled to an electronic apparatus other than the display apparatus 1001 (see FIG. 1), the semiconductor chip may be a chip for driving the electronic apparatus.

The semiconductor chip may be disposed in the circuit area 101 of the film substrate 100 and be mounted on the film substrate 100 through a flip chip bonding process. For example, connection terminals 231 may be disposed on chip pads exposed on an active surface of the third semiconductor chip 230. The connection terminals may be disposed on chip pads exposed on an active surface of each of the first and second semiconductor chips 210 and 220.

In this case, some of the chip pads of the third semiconductor chip 230 and some of the chip pads of the first and second semiconductor chips 210 and 220 may serve as input terminals, and the others of the chip pads of the third semiconductor chip 230 and the others of the chip pads of the first and second semiconductor chips 210 and 220 may serve as output terminals.

As such, the connection terminals 231 of the FIG. 6 are physically and electrically coupled to the second-third connection wirings 323, such that the gate driving chip and a plurality of source driving chips may be mounted on the film substrate 100.

In order to prevent external physical and/or chemical damage, the semiconductor chip 200 may be sealed with a sealing member such as an epoxy resin. Furthermore, an underfill (not illustrated) may be filled between the semiconductor chip and the film substrate 100. The underfill may be formed by, for example, a capillary underfill process. The underfill may be made of, for example, an epoxy resin, but is not limited thereto.

The connection wirings 300 may include first connection wirings 310 electrically connected to the display panel 700 and second connection wirings 320 electrically connected to the driving printed circuit board 600.

For example, the first-first direction Y1 described above may refer to a direction in which at least some of the first connection wirings 310 connected to the display panel 700 extend, and the first-second direction Y2 described above may refer to a direction in which at least some of the second connection wirings 320 connected to the driving printed circuit board 600 extend.

The first connection wirings 310 may be connected to first-first to first-third connection pads 311P, 312P, and 313P to be electrically connected to the display panel 700. The second connection wirings 320 may be connected to second-first to second-third connection pads 321P, 322P, and 323P to be electrically connected to the driving printed circuit board 600. The first-first to first-third connection pads 311P, 312P, and 313P and second-first to second-third connection pads 321P, 322P, and 323P can provide an exposed surface for forming the electrical connections.

The first connection wirings 310 may include first-first connection wirings 311 connected to the first semiconductor chip 210, first-second connection wirings 312 connected to the second semiconductor chip 220, and first-third connection wirings 313 connected to the third semiconductor chip 230.

Referring to FIG. 2, the first-first and first-second connection wirings 311 and 312 may be disposed on the upper layer 100TL of the film substrate 100. Referring to FIGS. 2 and 3 together, the first-third connection wirings 313 may be disposed on the lower layer 100BL of the film substrate 100 through through-vias 313V penetrating through the film substrate 100.

The first-first connection wirings 311 may be electrically connected to the first semiconductor chip 210 and the display panel 700 through the first-first connection pads 311P disposed on the upper layer 100TL of the film substrate 100. The first-second connection wirings 312 may be electrically connected to the second semiconductor chip 220 and the display panel 700 through the first-second connection pads 312P disposed on the upper layer 100TL of the film substrate 100. The first-third connection wirings 313 may be electrically connected to the third semiconductor chip 230 and the display panel 700 through the first-third connection pads 313P disposed on the lower layer 100BL of the film substrate 100. The first-third connection pads 313P and first-third connection wirings 313 on the lower layer 100BL may be electrically connected to the third semiconductor chip 230 on the upper layer 100TL through through-vias 313V penetrating through the film substrate 100. The first-third connection wirings 313 on the lower layer 100BL may extend beneath the first semiconductor chip 210.

The second connection wirings 320 may include second-first connection wirings 321 connected to the first semiconductor chip 210, second-second connection wirings 322 connected to the second semiconductor chip 220, and second-third connection wirings 323 connected to the third semiconductor chip 230. The second-first to second-third connection wirings 321, 322, and 323 may be disposed on the upper layer 100TL of the film substrate 100.

The second-first connection wirings 321 may be electrically connected to the first semiconductor chip 210 and the driving printed circuit board 600 through the second-first connection pads 321P disposed on the upper layer 100TL of the film substrate 100. The second-second connection wirings 322 may be electrically connected to the second semiconductor chip 220 and the driving printed circuit board 600 through the second-second connection pads 322P disposed on the upper layer 100TL of the film substrate 100. The second-third connection wirings 323 may be electrically connected to the third semiconductor chip 230 and the driving printed circuit board 600 through the second-third connection pads 323P disposed on the upper layer 100TL of the film substrate 100.

The connection wiring 300 may include, for example, a conductive material. For example, the connection wiring 300 may include at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C) or alloys thereof, but is not limited thereto.

The test pads 400 may be connected to at least one of the first and second connection wirings 310 and 320 in the circuit area 101 inside the cutting line CL. At least some of the test pads 400 may be disposed on the lower layer 100BL of the film substrate 100.

The test pads 400 may include first test pads 410 electrically connected to the first connection wirings 310 and second test pads 420 electrically connected to the second connection wirings 320.

The first test pads 410 may include first-first test pads 411TP electrically connected to the first-first connection wiring 311 through first-first test pad connection wirings 411, first-second test pads 412TP electrically connected to the first-second connection wirings 312 through first-second test pad connection wirings 412, and first-third test pads 413TP electrically connected to the first-third connection wirings 313 through the first-third test pad connection wirings 413.

Referring to FIG. 2, the first-first to first-third test pads 411TP, 412TP, and 413TP may be disposed on the upper layer 100TL of the film substrate 100. That is, test pads electrically connected to the display panel 700 may be disposed on the upper layer 100TL of the film substrate 100. The first-first to first-third test pads 411TP, 412TP, and 413TP may have a circular shape. The first-first to first-third test pads 411TP, 412TP, and 413TP may have a radius of 250 μm or more. The shape of the first-first to first-third test pads 411TP, 412TP, and 413TP are not limited thereto, and may be, for example, a polygonal shape.

The second test pads 420 may include second-first test pads 421TP electrically connected to the second-first connection wiring 321 through second-first test pad connection wirings 421, second-second test pads 422TP electrically connected to the second-second connection wirings 322 through second-second test pad connection wirings 422, and second-third test pads 423TP electrically connected to the second-third connection wirings 323 through second-third test pad connection wirings 423.

Referring to FIG. 2, the second-first and second-second test pads 421TP and 422TP may be disposed on the upper layer 100TL of the film substrate 100. However, referring to FIGS. 1 to 3 together, the second-third test pads 423TP may be disposed on the lower layer 100BL of the film substrate 100 between the third semiconductor chip 230 and the driving printed circuit board 600. In this case, the test pads may not be disposed in an area between the third semiconductor chip 230 and the driving printed circuit board 600 on the upper layer 100TL of the film substrate 100, so that a size of a component may be further reduced. The second-third test pads 423TP and second-third test pad connection wirings 423 on the lower layer 100BL may be electrically connected to the third semiconductor chip 230 on the upper layer 100TL through test pad connection vias 423V penetrating through the film substrate 100. The test pad connection via can penetrate through the film substrate 100 and electrically connecting a test pad and at least one of the first and second connection wirings to each other.

For example, the test pads 400 may be conductive pads for testing whether or not the display panel 700, the driving printed circuit board 600, and the semiconductor chips 210, 220, 230 are electrically connected.

For example, the test pad 400 may include at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C) or alloys thereof, but is not limited thereto.

Test pad connection vias 423V may electrically connect the second-third test pads 423TP and at least one of the first and second connection wirings 310 and 320, for example, the second-third connection wirings 323 to each other.

The second-third test pads 423TP may be electrically connected to the third semiconductor chip 230 through the second-third test pad connection wirings 423, the test pad connection vias 423V, and the second-third connection wirings 323. The second-third test pads 423TP may be electrically connected to the driving printed circuit board 600 through the second-third test pad connection wirings 423, the test pad connection vias 423V, the second-third connection wirings 323, and the second-third connection pads 323P.

The second-third test pad 423TP may have a circular shape. The second-third test pad 423TP may have a radius of 250 μm or more. The shape of the second-third test pad 423TP is not limited thereto, and may be, for example, a polygonal shape.

The test pad connection via 423V may include a conductive material. For example, the test pad connection via 423V may include at least one metal selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C) or alloys thereof, but is not limited thereto.

Referring to FIG. 6, the second-third test pad 423TP may be disposed between the third semiconductor chip 230 and the test pad connection via 423V, where the second-third test pad 423TP may be laterally offset from the test pad connection via 423V and an edge of the third semiconductor chip 230. However, positions of the test pads are not limited to those illustrated in the drawings. The test pad connection via 423V can penetrate the film substrate 100 and electrically connect a second-third connection wirings 323 on the upper layer 100TL to a second-third test pad connection wiring 423 on the lower layer 100BL.

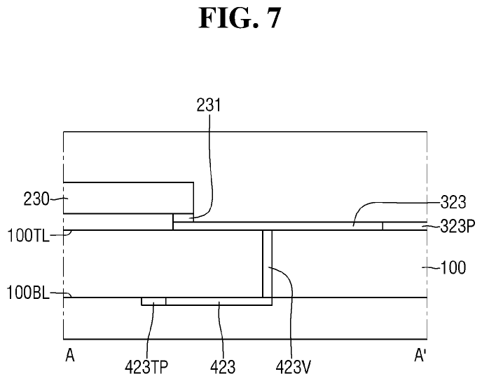

FIG. 7 is a schematic view for describing a chip on film package according to some exemplary embodiments of the present disclosure, and is a view corresponding to FIG. 6. For convenience of explanation, a description of the same contents as those described with reference to FIGS. 1 to 6 may be omitted.

Referring to FIG. 7, the second-third test pad 423TP may be disposed to at least partially overlap an inner area of the third semiconductor chip 230. In this case, for example, an extension length of the second-third test pad connection wiring 423 may be greater than that of the second-third test pad connection wiring 423 in FIG. 6. The second-third test pad 423TP may be positioned beneath the third semiconductor chip 230.

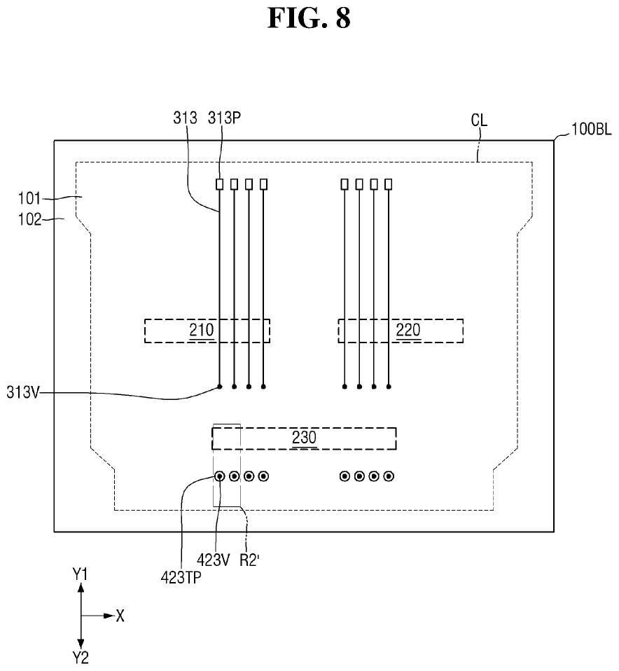

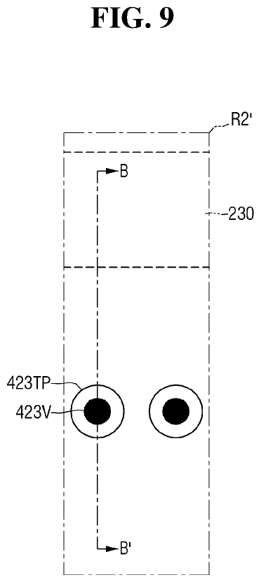

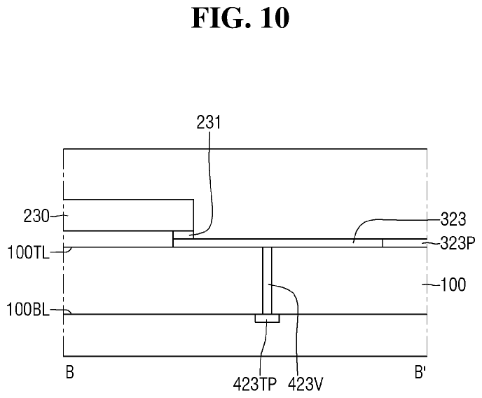

FIG. 8 is a schematic view for describing a chip on film package according to some exemplary embodiments of the present disclosure. FIG. 9 is an enlarged view of area R2′ of FIG. 8. FIG. 10 is a cross-sectional view taken along line B-B′ of FIG. 9. For convenience of explanation, a description of the same contents as those described with reference to FIGS. 1 to 7 may be omitted.

Referring to FIGS. 8 to 10, the second-third test pad 423TP may be in contact with the test pad connection via 423V. That is, unlike in FIGS. 2 to 7, the second-third test pad 423TP may be in direct contact with the test pad connection via 423V without the second-third test pad connection wiring 423. The second-third test pad 423TP may have a larger diameter than the test pad connection via 423V to provide a larger contact surface.

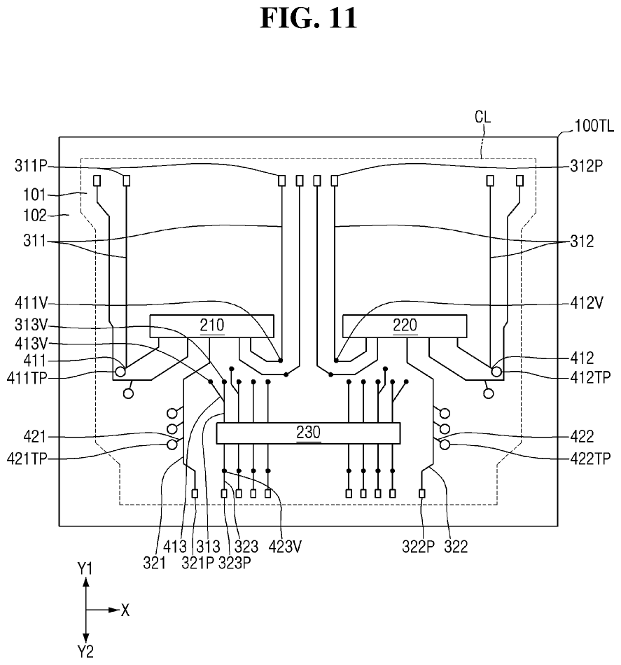

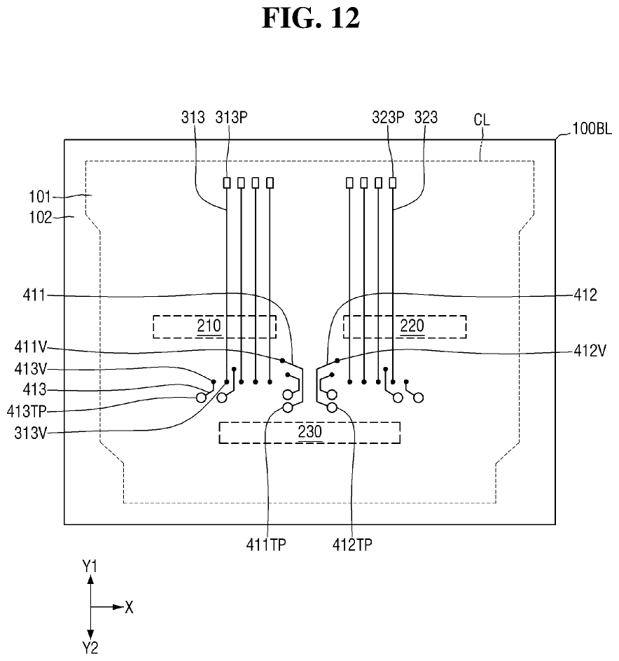

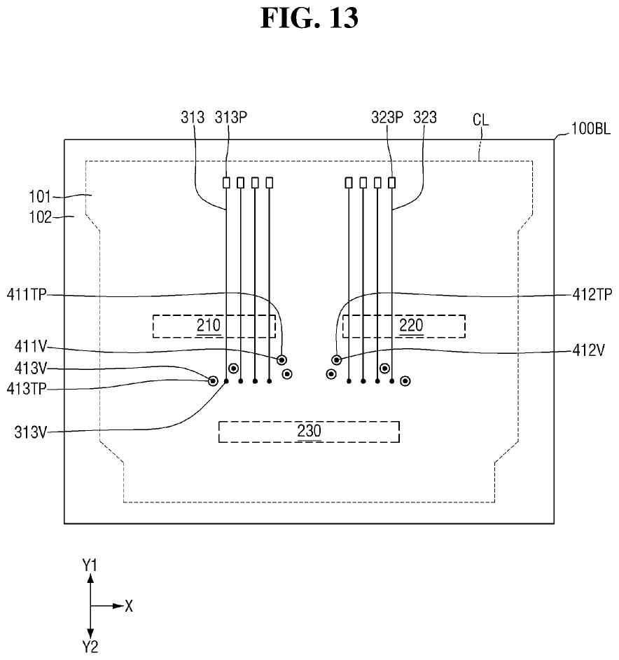

FIGS. 11 and 12 are schematic views for describing a chip on film package according to some exemplary embodiments of the present disclosure. FIG. 13 is a schematic view for describing a chip on film package according to some exemplary embodiments of the present disclosure. For convenience of explanation, a description of the same contents as those described with reference to FIGS. 1 to 10 may be omitted.

Referring to FIGS. 11 and 12, some of the first-first to first-third test pads 411TP, 412TP, and 413TP may be disposed on the lower layer 100BL of the film substrate 100.

The test pads disposed between the first and second semiconductor chips 210 and 220 among the first-first test pads 411TP and test pads disposed between the first and second semiconductor chips 210 and 220 among the first-second test pads 412TP may be disposed on the lower layer 100BL of the film substrate 100. The first-third connection wirings 313 interconnecting the first-third connection pads 313P and through-vias 313V may traverse beneath the semiconductor chip 210.

In addition, the first-third test pads 413TP disposed between the first to third semiconductor chips 210, 220, and 230 may be disposed on the lower layer 100BL of the film substrate 100.

The test pads disposed between the semiconductor chips among test pads electrically connected to the display panel 700 may be disposed on the lower layer 100BL of the film substrate 100.

In this case, the first-first test pads 411TP may be electrically connected to the first semiconductor chip 210 through the first-first test pad connection wirings 411 and test pad connection vias 411V. The first-second test pads 412TP may be electrically connected to the second semiconductor chip 220 through the first-second test pad connection wirings 412 and test pad connection vias 412V. In addition, the first-third test pads 413TP may be electrically connected to the third semiconductor chip 230 through the first-third test pad connection wirings 413 and test pad connection vias 413V.

Accordingly, the test pads may not be disposed in an area between the first to third semiconductor chips 210, 220, and 230 on the upper layer 100TL of the film substrate 100, so that a size of a component may be further reduced.

Referring to FIG. 13, unlike in FIG. 12, the first-first to first-third test pads 411TP, 412TP, and 413TP disposed between the first to third semiconductor chips 210, 220, and 230 may be in direct contact with the test pad connection vias 411V, 412V, and 413V, respectively.

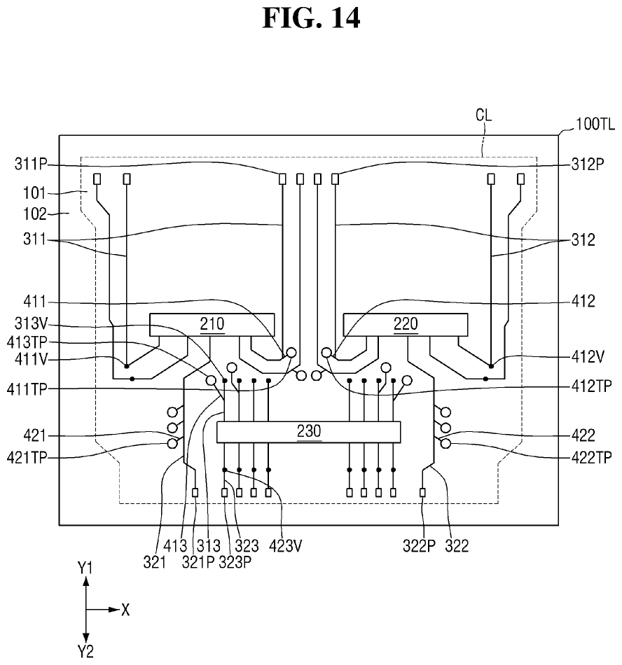

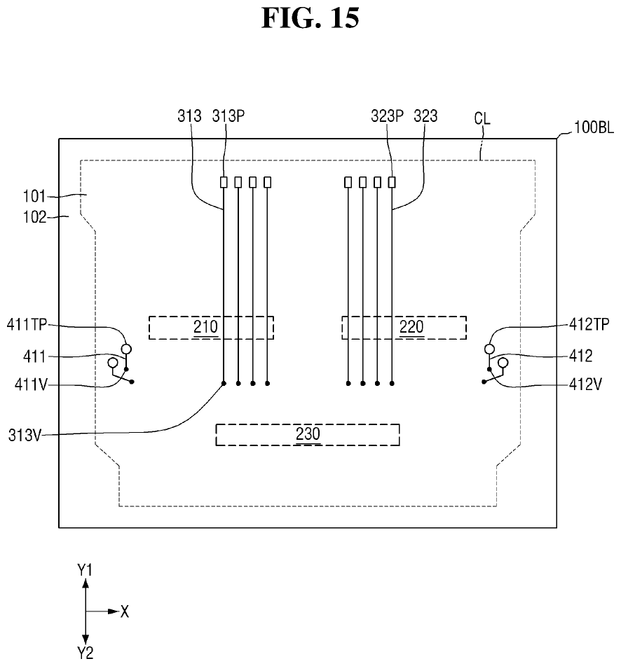

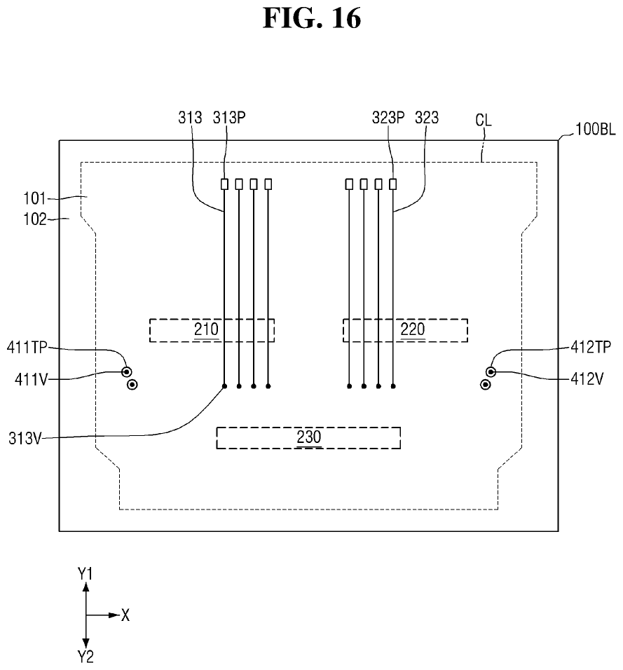

FIGS. 14 and 15 are schematic views for describing a chip on film package according to some exemplary embodiments of the present disclosure. FIG. 16 is a schematic view for describing a chip on film package according to some exemplary embodiments of the present disclosure. For convenience of explanation, a description of the same contents as those described with reference to FIGS. 1 to 13 may be omitted.

Referring to FIGS. 14 and 15, some of the first-first and first-third test pads 411TP and 412TP may be disposed on the lower layer 100BL of the film substrate 100.

The test pads connected to the first-first connection wirings 311 between the first semiconductor chip 210 and the display panel 700 among the first-first test pads 411TP and test pads connected to the first-second connection wirings 312 between the second semiconductor chip 220 and the display panel 700 among the first-second test pads 412TP may be disposed on the lower layer 100BL of the film substrate 100.

The test pads disposed adjacent to the outermost portion of the chip on film package 1000 among the test pads electrically connected to the display panel 700 may be disposed on the lower layer 100BL of the film substrate 100. The test pads disposed on the lower layer 100BL may be facing the display panel 700 and driving printed circuit board 600.

In this case, the first-first test pads 411TP may be electrically connected to the first semiconductor chip 210 through the first-first test pad connection wirings 411 and test pad connection vias 411V. The first-second test pads 412TP may be electrically connected to the second semiconductor chip 220 through the first-second test pad connection wirings 412 and test pad connection vias 412V.

Accordingly, the test pads may not be disposed in the outermost area between the semiconductor chips 210 and 220 and the display panel 700 on the upper layer 100TL of the film substrate 100, so that a size of a component may be further reduced.

Referring to FIG. 16, unlike in FIG. 15, the first-first and first-second test pads 411TP and 412TP disposed adjacent to the outermost portion of the chip on film package among the test pads electrically connected to the display panel 700 may be in direct contact with the test pad connection vias 411V and 412V, respectively.

Exemplary embodiments of the present disclosure have been described hereinabove with reference to the accompanying drawings, but the present disclosure is not limited to the above-described exemplary embodiments, and may be implemented in various different forms, and one of ordinary skill in the art to which the present disclosure pertains may understand that the present disclosure may be implemented in other specific forms without changing the technical spirit or essential features of the present disclosure. Therefore, it is to be understood that the exemplary embodiments described above are illustrative rather than being restrictive in all aspects.

What is claimed is:

1. A chip on film package comprising:
a film substrate including an upper layer extending in a first direction and a second direction opposite to each other and a lower layer facing the upper layer, and having a cutting line formed thereon;
first and second semiconductor chips disposed on the upper layer within an area of the cutting line;
first connection wirings connected to the first semiconductor chip and second connection wirings connected to the second semiconductor chip, wherein the first connection wirings and the second connection wirings; and
a test pad connected to at least one of the first and second connection wirings and disposed on the lower layer, within the area of the cutting line.

2. The chip on film package of claim 1, wherein the test pad is disposed between the first and second semiconductor chips.

3. The chip on film package of claim 1, wherein the first connection wiring is electrically connected to a display panel,
the second connection wiring is electrically connected to a driving printed circuit board, and
the test pad is disposed between the first semiconductor chip and the driving printed circuit board.

4. The chip on film package of claim 1, further comprising a test pad connection via penetrating through the film substrate and electrically connecting the test pad and at least one of the first and second connection wirings to each other.

5. The chip on film package of claim 4, wherein the test pad is in contact with the test pad connection via.

6. The chip on film package of claim 4, wherein the test pad is connected to the test pad connection via through a test pad connection wiring.

7. The chip on film package of claim 1, wherein the test pad has a circular shape.

8. The chip on film package of claim 1, wherein the test pad has a polygonal shape.

9. The chip on film package of claim 1, wherein the test pad has a radius of 250 μm or more.

10. The chip on film package of claim 1, wherein the upper layer further extends in a third direction crossing each of the first and second directions, and
the chip on film package further comprises a third semiconductor chip disposed on the upper layer and disposed to be spaced apart from the first and second semiconductor chips based on the third direction.

11. The chip on film package of claim 10, wherein the first connection wiring includes a first-first connection wiring connected to the first semiconductor chip, a first-second connection wiring connected to the second semiconductor chip, and a first-third connection wiring connected to the third semiconductor chip, and
the second connection wiring includes a second-first connection wiring connected to the first semiconductor chip, a second-second connection wiring connected to the second semiconductor chip, and a second-third connection wiring connected to the third semiconductor chip.

12. The chip on film package of claim 11, wherein the first-first and first-second connection wirings are disposed on the upper layer, and the first-third connection wiring is disposed on the lower layer through a through-via penetrating through the film substrate.

13. A chip on film package comprising:
a film substrate including an upper layer and a lower layer facing each other and having a cutting line formed thereon;
first and second connection wirings electrically connected to a display panel and a driving printed circuit board, respectively;
first to third semiconductor chips electrically connected to the first and second connection wirings, on the upper layer of the film substrate;
a test pad disposed inside the cutting line and electrically connected to at least one of the first and second connection wirings; and
a test pad connection via penetrating through the film substrate,
wherein the test pad is disposed on the lower layer of the film substrate.

14. The chip on film package of claim 13, wherein the test pad is disposed between the first to third semiconductor chips.

15. The chip on film package of claim 13, wherein the test pad is disposed between the third semiconductor chip and the driving printed circuit board.

16. The chip on film package of claim 13, wherein the first connection wiring includes a first-first connection wiring connected to the first semiconductor chip, a first-second connection wiring connected to the second semiconductor chip, and a first-third connection wiring connected to the third semiconductor chip,
the second connection wiring includes a second-first connection wiring connected to the first semiconductor chip, a second-second connection wiring connected to the second semiconductor chip, and a second-third connection wiring connected to the third semiconductor chip, and
the first-third connection wiring is disposed on the lower layer through a through-via penetrating through the film substrate.

17. The chip on film package of claim 13, wherein the test pad connection via electrically connects the test pad and at least one of the first and second connection wirings to each other.

18. The chip on film package of claim 13, wherein the test pad is in contact with the test pad connection via.

19. A display apparatus comprising:
a chip on film package including a film substrate including an upper layer extending in first and second directions opposite to each other and a third direction crossing each of the first and second directions and a lower layer facing the upper layer and having a cutting line formed thereon;
a display panel formed on a first side of the chip on film package; and
a driving printed circuit board formed on a second side of the chip on film package,
wherein the chip on film package includes:
first to third semiconductor chips disposed on the upper layer within an area of the cutting line;
first (311 and 321), second (312 and 322), to third connection wirings (313 and 323) connected to the first to third semiconductor chips, respectively, and electrically connected to the display panel and the driving printed circuit board;
connection vias penetrating through the film substrate and connected to the first to third connection wirings; and
a test pad connected to at least one of the first to third connection wirings through the connection vias and disposed on the lower layer, within the area of the cutting line.

20. The display apparatus of claim 19, wherein the third connection wiring includes a third-first connection wiring (323) electrically connected to the driving printed circuit board and a third-second connection wiring (313) electrically connected to the display panel,
the third-first connection wiring is disposed on the upper layer, and
the third-second connection wiring is disposed on the lower layer through a through-via penetrating through the film substrate.
